(19) United States
(12) Patent Application Publication
(10) Pub. No.: US 2026/0255946 A1
(43) Pub. Date: Aug. 27, 2026

(54) INTEGRATED CIRCUIT DEVICES INCLUDING A CONDUCTIVE VIA AND METHODS OF FORMING THE SAME

(71) Applicant: Samsung Electronics Co., Ltd., Suwon-si (KR)

(72) Inventors: Gwang-Sik Kim, Clifton Park, NY (US); Beomjin Park, Halfmoon, NY (US); Young Gook Park, Rensselaer, NY (US); Jongmin Shin, Schenectady, NY (US); Kang-ill Seo, Springfield, VA (US)

(21) Appl. No.: 19/279,403

(22) Filed: Jul. 24, 2025

Related U.S. Application Data
(60) Provisional application No. 63/763,369, filed on Feb. 26, 2025.

(51) Int. Cl. H01L 23/522; H01L 21/768; H01L 23/528; H10D 1/00; H10D 1/68

(52) U.S. Cl. CPC H10W 20/42; H10D 1/042; H10D 1/716; H10W 20/056; H10W 20/435; H10W 20/496; H10W 20/498

(57) ABSTRACT

An integrated circuit device includes a substrate, an insulating layer on the substrate, a first conductive pattern on the insulating layer, a second conductive pattern in the insulating layer, and a first via between the first conductive pattern and the second conductive pattern. The second conductive pattern is between the substrate and the first conductive pattern in a direction that is perpendicular to an upper surface of the substrate. The second conductive pattern is spaced apart from the first conductive pattern in the direction. The first via is in contact with one of the first conductive pattern and the second conductive pattern. The first via is spaced apart from the other one of the first conductive pattern and the second conductive pattern in the direction.

### CROSS-REFERENCE TO RELATED APPLICATIONS

This application claims priority to U.S. Provisional Application Ser. No. 63/763,369 entitled INTEGRATED CIRCUIT DEVICES WITH DUAL VIA SCHEME AND METHODS OF MANUFACTURING THE SAME, filed in the USPTO on Feb. 26, 2025, the disclosure of which is hereby incorporated by reference herein in its entirety.

### TECHNICAL FIELD

The present disclosure generally relates to the field of electronics and, more particularly, to integrated circuit devices.

Various back end of line (BEOL) structures of an integrated circuit device with different configurations and materials have been suggested to reduce resistance and process complexity thereof so as to improve the performance and the production yield of the integrated circuit device.

### SUMMARY

An aspect of the present disclosure is to provide integrated circuit devices with conductive patterns and conductive vias formed by different manufacturing methods. An aspect of the present disclosure is to provide integrated circuit devices with a dual conductive via scheme formed by different manufacturing methods. An aspect of the present disclosure is to provide integrated circuit devices with conductive vias formed by a top via scheme and a damascene scheme. However, it will be understood that the embodiments, goals, and benefits of the present disclosure are not limited to the descriptions above.

According to some embodiments, an integrated circuit device may include a substrate, an insulating layer on the substrate, a first conductive pattern on the insulating layer, and a second conductive pattern in the insulating layer. The second conductive pattern may be between the substrate and the first conductive pattern in a direction that is perpendicular to an upper surface of the substrate. The second conductive pattern may be spaced apart from the first conductive pattern in the direction. The integrated circuit device may also include a first via between the first conductive pattern and the second conductive pattern in the direction. The first via may be in contact with one of the first conductive pattern and the second conductive pattern. The first via may be spaced apart from the other one of the first conductive pattern and the second conductive pattern in the direction.

According to some embodiments, an integrated circuit device may include a substrate, a first insulating layer on the substrate, first conductive patterns in the first insulating layer, a second insulating layer between the first insulating layer and the substrate in a first direction that is perpendicular to an upper surface of the substrate, and second conductive patterns in the second insulating layer. The second conductive patterns may be spaced apart from each other in a second direction that is parallel with the upper surface of the substrate. The integrated circuit devices may also include vias between the first conductive patterns and the second conductive patterns in the first direction. One of the vias may protrude from one among the first conductive patterns and the second conductive patterns in the first direction. The one of the vias may be spaced apart from another one among the first conductive patterns and the second conductive patterns in the first direction. The one among the first conductive patterns and the second conductive patterns may be opposite to the another one among the first conductive patterns and the second conductive patterns in the first direction.

According to some embodiments, a method of forming an integrated circuit devices may include forming first conductive patterns and a first via on a substrate by a first process, and forming second conductive patterns and a second via on the first conductive patterns and the first via by a second process. The first via may protrude from one of the first conductive patterns toward the second conductive patterns and may be spaced apart from the second conductive patterns. The second via may protrude from one of the second conductive patterns toward the first conductive patterns and may be spaced apart from the first conductive patterns.

### BRIEF DESCRIPTION OF THE DRAWINGS

FIG. 1 is a cross-sectional view of an integrated circuit device according to some embodiments.

FIG. 1A is an enlarged view of a portion A of FIG. 1.

FIG. 1B is an enlarged view of a portion B of FIG. 1.

FIG. 1C is an enlarged view of a portion C of FIG. 1.

FIG. 1D is an enlarged view of a portion D of FIG. 1.

FIG. 1E is an enlarged view of a portion E of FIG. 1.

FIG. 2 is a flow chart of methods of forming an integrated circuit device according to some embodiments.

FIGS. 3 through 10 are cross-sectional views, illustrating methods of forming an integrated circuit device in FIG. 1 according to some embodiments. FIG. 3 is a cross-sectional view of an intermediate process, including forming a preliminary conductive pattern in a sacrificial layer on a substrate. FIG. 4 is a cross-sectional view of an intermediate process, including forming a mask pattern on the preliminary conductive pattern. FIG. 5 is a cross-sectional view of an intermediate process, including recessing the preliminary conductive pattern to form a second conductive pattern and a second conductive via. FIG. 6 is a cross-sectional view of an intermediate process, including removing the mask pattern and the sacrificial layer. FIG. 7 is a cross-sectional view of an intermediate process, including forming a second insulating layer. FIG. 8 is a cross-sectional view of an intermediate process, including forming a first insulating layer on the second insulating layer. FIG. 9 is a cross-sectional view of an intermediate process, including forming a first opening in the first insulating layer and a second opening in the second insulating layer. FIG. 10 is a cross-sectional view of an intermediate process, including forming a first conductive layer in the first opening and the second opening.

### DETAILED DESCRIPTION

Conductive material(s), such as metal(s) (e.g., ruthenium (Ru), molybdenum (Mo), tungsten (W), aluminum (Al), and/or copper (Cu)), may be used to form conductive elements (e.g., a conductive pattern and a conductive via) in a BEOL structure. Various methods of forming the conductive elements have been studied. One of the methods of forming the conductive elements may include a damascene process. For example, a first opening may be formed in a first insulating layer, and a second opening may be formed in a second insulating layer that is on the first insulating layer. Then, a conductive layer may be formed in the first opening and the second opening. A chemical mechanical polishing (planarization) (CMP) process may be performed to form a conductive pattern and a conductive via in the first opening and the second opening, respectively, by removing a portion of the conductive layer. The damascene process may be used to form conductive elements comprising a non-etchable material (a non-subtractable material), such as Cu or other metals that may not be patterned using some etching techniques. As the pitches of the conductive elements shrink, the damascene process may encounter various challenges, such as properly filling the first and second openings with the conductive layer. To simplify the manufacturing process of the BEOL structure, increase the integration degree of various elements in the integrated circuit device, and improve (e.g., reduce) the resistance of the BEOL structure, a top via scheme utilizing an etchable material (a subtractable material) may be used. For example, Ru top via scheme may utilize an etching process of Ru to form conductive elements, such as a conductive pattern and a conductive via, and may not require a damascene process. However, the top via scheme may also face some challenges, such as etching (recess) variation and pattern flopovers.

According to aspects of the present disclosures, the integrated circuit device may include a BEOL structure with a dual conductive via scheme. For example, a lower conductive pattern and a lower conductive via of the BEOL structure may be formed by a top via scheme. On the other hand, an upper conductive pattern and an upper conductive via of the BEOL structure may be formed by a damascene process. Each of the upper conductive via and the lower conductive via may be referred to as a half conductive via. Herein, the half conductive via is not limited that each of the half conductive vias has the exact half height of the total height of the (corresponding) conductive vias. In other words, the half conductive via may be a fractional conductive via. For example, the height of the upper conductive via (the first conductive via) may be different from the height of the lower conductive via (the second conductive via). The dual conductive via scheme may resolve various challenges of conductive element formation described above in advanced interconnect technologies with (extremely) narrow pitches. Also, the dual conductive via scheme may enhance design flexibility for various device elements, such as interconnection structure, e-fuses (e.g., anti-fuses), and metal-oxide-metal capacitors (MOMCAPs).

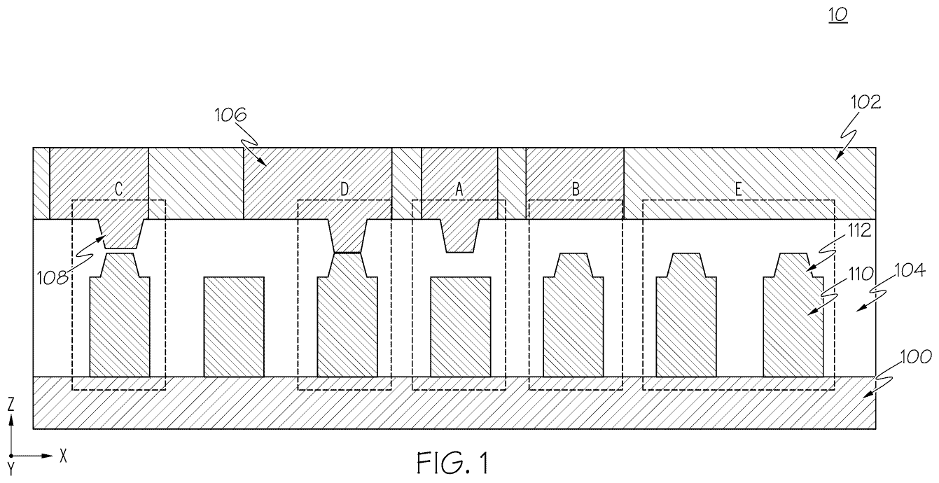

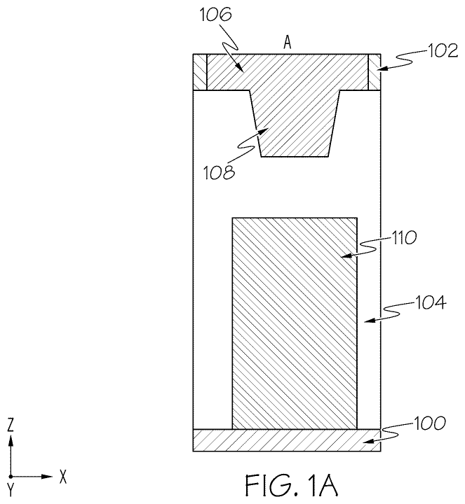

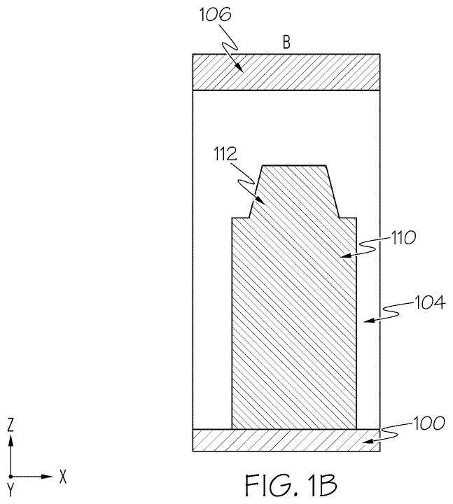

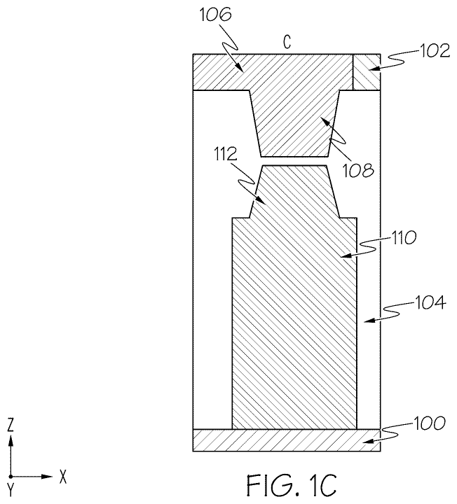

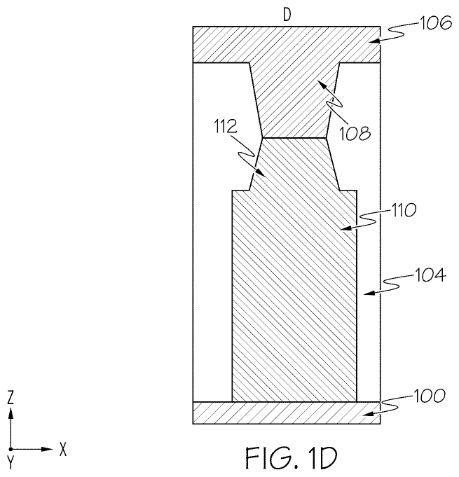

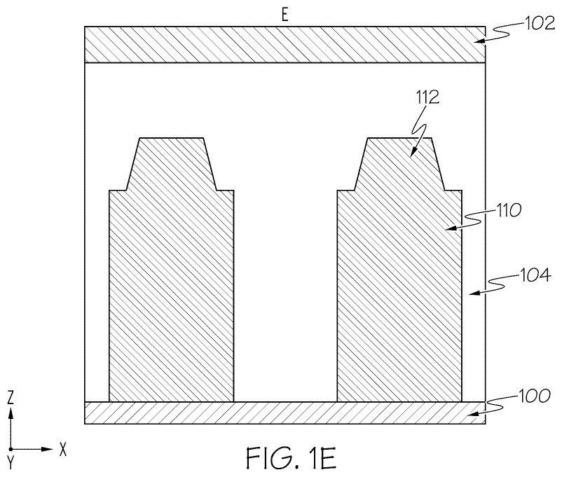

FIG. 1 is a cross-sectional view of an integrated circuit device 10 according to some embodiments. FIG. 1A is an enlarged view of a portion A of FIG. 1. FIG. 1B is an enlarged view of a portion B of FIG. 1. FIG. 1C is an enlarged view of a portion C of FIG. 1. FIG. 1D is an enlarged view of a portion D of FIG. 1. FIG. 1E is an enlarged view of a portion E of FIG. 1.

The integrated circuit device 10 may include a substrate 100. The substrate 100 may be on a front-end-of-line (FEOL)/middle-end-of-line (MEOL) structure (not illustrated) that includes elements formed during FEOL and MEOL processes. The substrate 100 may be between the FEOL/MEOL structure and a BEOL structure in a first direction that is perpendicular to an upper surface of the substrate 100 (e.g., Z-direction). For example, the FEOL/MEOL structure may include transistors and/or capacitors, and the BEOL structure may include conductive elements, such as conductive patterns (e.g., metal patterns) and/or conductive vias (e.g., metal vias). Referring to FIG. 1, the BEOL structure may include a first insulating layer 102, a second insulating layer 104, a first conductive pattern 106, a first conductive via 108, a second conductive pattern 110, and a second conductive via 112, which will be described in detail below. Herein, each of the first conductive via 108 (upper conductive via) and the second conductive via 112 (lower conductive via) may be referred to as a half conductive via.

The substrate 100 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material, but embodiments are not limited thereto. In some embodiments, the substrate 100 may be a bulk substrate (e.g., a silicon wafer), a semiconductor on insulator (SOI) substrate or an insulating layer (e.g., a monolithic insulating layer). Herein, the low-k material may be a material having a dielectric constant lower than that of silicon oxide. The low-k material may include, for example, SiCOH, fluorine-doped silicon oxide, organosilicate glass, carbon-doped oxide, porous silicon dioxide, porous organosilicate glass, spin-on organic polymeric dielectrics and/or spin-on silicon based polymeric dielectric.

The first insulating layer 102 may be on (the upper surface of) the substrate 100. The second insulating layer 104 may be between the first insulating layer 102 and the substrate 100 in the first direction. Each of the first insulating layer 102 and the second insulating layer 104 may include an insulating material, such as silicon oxide, silicon oxynitride, silicon nitride, silicon carbonitride and/or a low-k material, but the embodiments are not limited thereto. In some embodiments, the first insulating layer 102 may include a different material from that of the second insulating layer 104.

The first conductive pattern 106 may be in the first insulating layer 102. In some embodiments, the first insulating layer 102 may extend around the first conductive pattern 106. The first conductive pattern 106 may extend into (e.g., penetrate through) the first insulating layer 102 in the first direction. In some embodiments, a lower surface of the first conductive pattern 106 may be coplanar with a lower surface of the first insulating layer 102 (coplanar with an upper surface of the second insulating layer 104). For example, the first conductive pattern 106 may not be in the second insulating layer 104. The first conductive pattern 106 may overlap the first insulating layer 102 in a second direction that is parallel with the upper surface of the substrate (e.g., X-direction). The first conductive pattern 106 may not overlap the second insulating layer 104 in the second direction. As used herein, “an element A overlapping an element B in a direction C” (or similar language) means that there is at least one line that extends in the direction C and intersects both the elements A and B. The first conductive pattern 106 may include a conductive material. In some embodiments, the first conductive pattern 106 may include a metal, such as Ru, Mo, W, Cu, and/or Al, but the embodiments are not limited thereto. In some embodiments, the first conductive pattern 106 may include a non-etchable metal (e.g., non-subtractable metal), such as Cu.

The first conductive via 108 may be between the first conductive pattern 106 and the second conductive pattern 110 (in the first direction). The first conductive via 108 may be in the second insulating layer 104. In some embodiments, the second insulating layer 104 may extend around the first conductive via 108. The first conductive via 108 may extend into the second insulating layer 104 in the first direction. In some embodiments, an upper surface of the first conductive via 108 may be coplanar with the lower surface of the first insulating layer 102 (coplanar with the upper surface of the second insulating layer 104). A lower surface of the first conductive pattern 106 may be coplanar with the lower surface of the first insulating layer 102. For example, the upper surface of the first conductive via 108 and the lower surface of the first conductive pattern 106 may be bound to each other (to form an interface between the first conductive via 108 and the first conductive pattern 106). A lower surface of the first conductive via 108 may be in contact with the second insulating layer 104 and/or an upper surface of the second conductive via 112. For example, the first conductive via 108 may not be in the first insulating layer 102. The first conductive via 108 may overlap the second insulating layer 104 in the second direction. The first conductive via 108 may not overlap the first insulating layer 102 in the second direction. The first conductive via 108 may include a conductive material. In some embodiments, the first conductive via 108 may include a metal, such as Ru, Mo, W, Cu, and/or Al, but the embodiments are not limited thereto. In some embodiments, the first conductive via 108 may include a non-etchable metal (e.g., non-subtractable metal), such as Cu.

The first conductive pattern 106 may be (electrically) connected to (e.g., may be in contact with) the first conductive via 108. For example, the lower surface of the first conductive pattern 106 and the upper surface of the first conductive via 108 may be in contact with each other at the lower surface of the first insulating layer 102 (the upper surface of the second insulating layer 104). In some embodiments, the first conductive pattern 106 and the first conductive via 108 may include the same material. In some embodiments, the first conductive pattern 106 and the (corresponding) first conductive via 108 may be integrated with each other as a first monolithic conductive structure. A monolithic structure (e.g., the first monolithic conductive structure) herein may refer to a structure (e.g., a continuum) without a (visible) boundary between its sub-structures (e.g., the first conductive pattern 106 and the first conductive via 108). In some embodiment, the first conductive via 108 may protrude from the first conductive pattern 106 toward the substrate 100 in the first direction. For example, the first conductive via 108 may protrude from the first conductive pattern 106 toward the second conductive via 112 and/or the second conductive pattern 110 in the first direction.

In some embodiments, a plurality of first conductive patterns 106 may be in the first insulating layer 102, and a plurality of first conductive vias 108 may be in the second insulating layer 104. One among the plurality of first conductive vias 108 may overlap a corresponding one among the plurality of first conductive patterns 106 in the first direction. In some embodiments, one among the plurality of first conductive patterns 106 may not overlap the plurality of first conductive vias 108 in the first direction. For example, one among the plurality of first conductive patterns 106 may not have the first conductive via 108 thereon. The one among the plurality of first conductive patterns 106 may not be (electrically) connected to (may not be in contact with) the first conductive via 108.

The second conductive pattern 110 may be between the substrate 100 and the first conductive pattern 106 (in the first direction). The second conductive pattern 110 may be spaced apart from the first conductive pattern 106 (in the first direction). The second conductive pattern 110 may be in the second insulating layer 104. In some embodiments, the second insulating layer 104 may extend around the second conductive pattern 110. The second conductive pattern 110 may extend into the second insulating layer 104 in the first direction. In some embodiments, a lower surface of the second conductive pattern 110 may be coplanar with a lower surface of the second insulating layer 104 (e.g., coplanar with the upper surface of the substrate 100). The second conductive pattern 110 may not be in the first insulating layer 102. The second conductive pattern 110 may overlap the second insulating layer 104 in the second direction. The second conductive pattern 110 may not overlap the first insulating layer 102 in the second direction. The second conductive pattern 110 may include a conductive material. In some embodiments, the second conductive pattern 110 may include a metal, such as Ru, Mo, W, Cu, and/or Al, but the embodiments are not limited thereto. In some embodiments, the second conductive pattern 110 may include an etchable metal (e.g., a subtractable metal), such as Ru.

The second conductive via 112 may be between the first conductive pattern 106 and the second conductive pattern 110 (in the first direction). The second conductive via 112 may be in the second insulating layer 104. In some embodiments, the second insulating layer 104 may extend around the second conductive via 112. The second conductive via 112 may extend into the second insulating layer 104 in the first direction. In some embodiments, the upper surface of the second conductive via 112 may be in contact with the second insulating layer 104 and/or the lower surface of the first conductive via 108. For example, the second conductive via 112 may not be in the first insulating layer 102. The second conductive via 112 may overlap the second insulating layer 104 in the second direction. The second conductive via 112 may not overlap the first insulating layer 102 in the second direction. The second conductive via 112 may include a conductive material. In some embodiments, the second conductive via 112 may include a metal, such as Ru, Mo, W, Cu, and/or Al, but the embodiments are not limited thereto. In some embodiments, the second conductive via 112 may include an etchable metal (e.g., a subtractable metal), such as Ru. In some embodiments, the material of (in) the second conductive via 112 and the second conductive pattern 110 may be different from the material of (in) the first conductive via 108 and the first conductive pattern 106.

The second conductive pattern 110 may be (electrically) connected to (e.g., may be in contact with) the second conductive via 112. For example, an upper surface of the second conductive pattern 110 and a lower surface of the second conductive via 112 may be in contact with each other. For example, the upper surface of the second conductive pattern 110 and the lower surface of the second conductive via 112 may be bound to each other (to form an interface). In some embodiments, the second conductive pattern 110 and the second conductive via 112 may include the same material. In some embodiments, the second conductive pattern 110 and the (corresponding) second conductive via 112 may be integrated with each other as a second monolithic conductive structure. In some embodiment, the second conductive via 112 may protrude from the second conductive pattern 110 toward the first insulating layer 102 in the first direction. For example, the second conductive via 112 may protrude from the second conductive pattern 110 toward the first conductive via 108 and/or the first conductive pattern 106 in the first direction.

In some embodiments, a plurality of second conductive patterns 110 may be in the second insulating layer 104, and a plurality of second conductive vias 112 may be in the second insulating layer 104. One among the plurality of second conductive vias 112 may overlap a corresponding one among the plurality of second conductive patterns 110 in the first direction. In some embodiments, one among the plurality of second conductive patterns 110 may not overlap the plurality of second conductive vias 112 in the first direction. For example, one among the plurality of second conductive patterns 110 may not have the second conductive via 112 thereon. The one among the plurality of second conductive patterns 110 may not be (electrically) connected to (may not be in contact with) the second conductive via 112.

In some embodiments, a width in the second direction of the first conductive via 108 may be less than a width in the second direction of the first conductive pattern 106. For example, a width in the second direction of the upper surface (or an upper portion) of the first conductive via 108 may be less than a width in the second direction of the lower surface of the first conductive pattern 106. For example, the upper surface of the first conductive via 108 and the lower surface of the first conductive pattern 106 may be bound to each other. In some embodiments, a width in the second direction of the first conductive via 108 may decrease in a direction away from the first conductive pattern 106. For example, the first conductive via 108 may have a reverse trapezoidal shape in a cross-sectional view, but the embodiments are not limited thereto. In some embodiments, a side surface of the first conductive pattern 106 and a side surface of the first conductive via 108 may have a step difference therebetween.

In some embodiments, a width in the second direction of the second conductive via 112 may be less than a width in the second direction of the second conductive pattern 110. For example, a width in the second direction of the lower surface (or a lower portion) of the second conductive via 112 may be less than a width in the second direction of the upper surface of the second conductive pattern 110. In some embodiments, a width in the second direction of the lower surface of the second conductive via 112 may be equal to a width in the second direction of the upper surface of the second conductive pattern 110. The lower surface of the second conductive via 112 and the upper surface of the second conductive pattern 110 may be bound to each other. In some embodiments, a width in the second direction of the second conductive via 112 may decrease in a direction away from the second conductive pattern 110. For example, the second conductive via 112 may have a trapezoidal shape in a cross-sectional view, but the embodiments are not limited thereto. In some embodiments, a side surface of the second conductive pattern 110 and a side surface of the second conductive via 112 may have a step difference therebetween, but the embodiments are not limited thereto. For example, although not illustrated, a side surface of the second conductive pattern 110 and a side surface of the second conductive via 112 may be configured as a continuous surface without a step difference therebetween.

Referring to FIGS. 1 and 1A, the first conductive via 108 may protrude from the first conductive pattern 106 toward the second conductive pattern 110 (in the first direction). The first conductive via 108 may be in contact with the first conductive pattern 106. The first conductive via 108 may be spaced apart from the second conductive pattern 110 (in the first direction). The first conductive via 108 may be spaced apart from the second conductive pattern 110 by the second insulating layer 104. In some embodiments, the first conductive via 108, the second conductive pattern 110, and the second insulating layer 104 therebetween may be configured as an e-fuse (e.g., an anti-fuse). For example, (without a voltage bias) the first conductive via 108 and the second conductive pattern 110 may be electrically separated by the second insulating layer 104. When a certain voltage level (a voltage bias) is applied, the second insulating layer 104 may break down, and the first conductive via 108 and the second conductive pattern 110 may become electrically connected. In some example embodiments, the distance between the first conductive via 108 and the second conductive pattern 110 in the first direction may be (around) 15 to 20 nanometers (nm), and the breakdown voltage level between the first conductive via 108 and the second conductive pattern 110 may be (around) 4 to 5 volts (V). However, the embodiments of the distance and breakdown voltage level between the first conductive via 108 and the second conductive pattern 110 are not limited to the descriptions above. The anti-fuse structure comprising the first conductive via 108, the second conductive pattern 110, and the second insulating layer 104 therebetween may be configured (to perform) as a one-time programmable memory device. In some embodiments, the first conductive via 108, the second conductive pattern 110, and the second insulating layer 104 therebetween may be configured as a MOMCAP.

Referring to FIGS. 1 and 1B, the second conductive via 112 may protrude from the second conductive pattern 110 toward the first conductive pattern 106 (in the first direction). The second conductive via 112 may be in contact with the second conductive pattern 110. The second conductive via 112 may be spaced apart from the first conductive pattern 106 (in the first direction). The second conductive via 112 may be spaced apart from the first conductive pattern 106 by the second insulating layer 104. In some embodiments, the second conductive via 112, the first conductive pattern 106, and the second insulating layer 104 therebetween may be configured as an e-fuse (e.g., an anti-fuse). For example, (without a voltage bias) the second conductive via 112 and the first conductive pattern 106 may be electrically separated by the second insulating layer 104. When a certain voltage level (a voltage bias) is applied, the second insulating layer 104 may break down, and the second conductive via 112 and the first conductive pattern 106 may become electrically connected. The anti-fuse structure comprising the second conductive via 112, the first conductive pattern 106, and the second insulating layer 104 therebetween may be configured (to perform) as a one-time programmable memory device. In some embodiments, the second conductive via 112, the first conductive pattern 106, and the second insulating layer 104 therebetween may be configured as a MOMCAP.

Referring to FIGS. 1 and 1C, the first conductive via 108 may protrude from the first conductive pattern 106 toward the second conductive via 112 (in the first direction). The second conductive via 112 may protrude from the second conductive pattern 110 toward the first conductive via 108 (in the first direction). The first conductive via 108 may overlap the second conductive via 112 in the first direction. The first conductive via 108 may be in contact with the first conductive pattern 106. The second conductive via 112 may be in contact with the second conductive pattern 110. The first conductive via 108 and the second conductive via 112 may be spaced apart from each other (in the first direction). The first conductive via 108 and the second conductive via 112 may be spaced apart from each other by the second insulating layer 104. In some embodiments, a thickness in the first direction of the second insulating layer 104 between the first conductive via 108 and the second conductive via 112 illustrated in FIG. 1C may be less than a thickness in the first direction of the second insulating layer 104 between the first conductive via and the second conductive pattern 110 illustrated in FIG. 1A and less than a thickness in the first direction of the second insulating layer 104 between the first conductive pattern 106 and the second conductive via 112 illustrated in FIG. 1B. In some embodiments, the first conductive via 108, the second conductive via 112, and the second insulating layer 104 therebetween may be configured as an e-fuse (e.g., an anti-fuse). For example, (without a voltage bias) the first conductive via 108 and the second conductive via 112 may be electrically separated by the second insulating layer 104. When a certain voltage level (a voltage bias) is applied, the second insulating layer 104 may break down, and the first conductive via 108 and the second conductive via 112 may become electrically connected. The anti-fuse structure comprising the first conductive via 108, the second conductive via 112, and the second insulating layer 104 therebetween may be configured (to perform) as a one-time programmable memory device. In some embodiments, the first conductive via 108, the second conductive via 112, and the second insulating layer 104 therebetween may be configured as a MOMCAP.

Referring to FIGS. 1 and 1D, the first conductive via 108 may protrude from the first conductive pattern 106 toward the second conductive via 112 (in the first direction). The second conductive via 112 may protrude from the second conductive pattern 110 toward the first conductive via 108 (in the first direction). The first conductive via 108 may overlap the second conductive via 112 in the first direction. The first conductive via 108 may be in contact with the first conductive pattern 106. The second conductive via 112 may be in contact with the second conductive pattern 110. The first conductive via 108 may be in contact with the second conductive via 112. For example, a lower surface of the first conductive via 108 may be in contact with an upper surface of the second conductive via 112. In some embodiments, the first conductive via 108 and the second conductive via 112 may be configured as an interconnection structure between the first conductive pattern 106 and the second conductive pattern 110. The first conductive via 108 may be electrically connected to the second conductive via 112. The first conductive pattern 106 may be electrically connected to the second conductive pattern 110 through the interconnection structure.

Referring to FIGS. 1 and 1E, a plurality of second conductive patterns 110 may be arranged to be spaced apart from each other in the second direction. Adjacent ones of the plurality of second conductive patterns 110 may have the second insulating layer 104 therebetween (in the second direction). Each of the adjacent ones of the plurality of second conductive patterns 110 may have the second conductive via 112 thereon. The adjacent ones of the plurality of second conductive patterns 110 with the second conductive vias 112 and the second insulating layer 104 therebetween may be configured as a MOMCAP. As the height of the second monolithic conductive structure in the first direction is greater than that of the second conductive pattern 110 because of the second conductive via 112 on the second conductive pattern 110, the capacitance of the MOMCAP may increase.

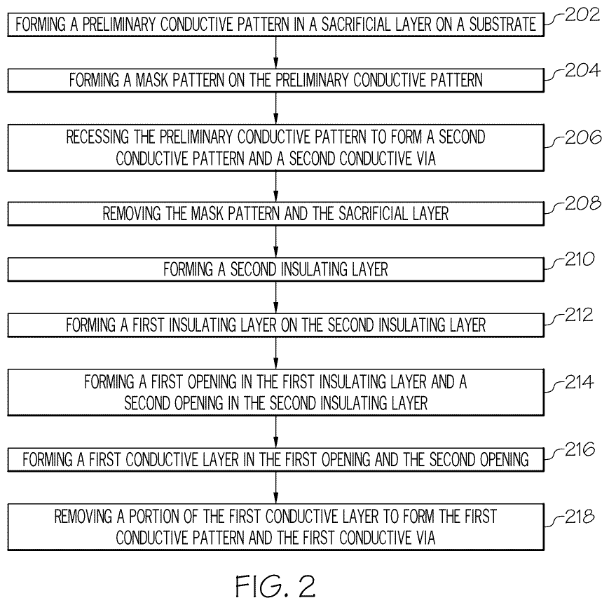

FIG. 2 is a flow chart of methods of forming an integrated circuit device (e.g., the integrated circuit device 10 in FIG. 1) according to some embodiments.

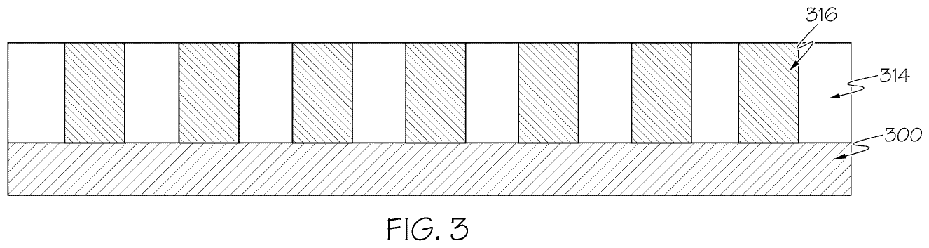

FIGS. 3 through 10 are cross-sectional views, illustrating methods of forming an integrated circuit device 10 in FIG. 1 according to some embodiments. FIG. 3 is a cross-sectional view of an intermediate process, including forming a preliminary conductive pattern 316 in a sacrificial layer 314 on a substrate 300 (Block 202 in FIG. 2). In some embodiments, a plurality of preliminary conductive patterns 316 may be formed in the sacrificial layer 314 on the substrate 300.

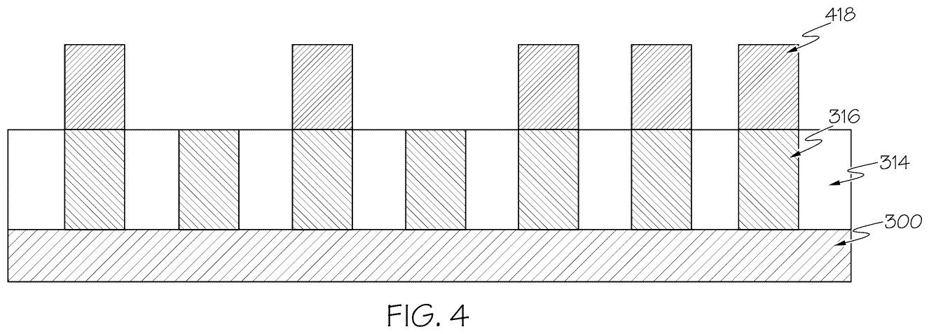

FIG. 4 is a cross-sectional view of an intermediate process, including forming a mask pattern 418 on (an upper surface of) the preliminary conductive pattern 316 (Block 204 in FIG. 2). In some embodiments, at least one among the plurality of preliminary conductive patterns 316 may not have the mask pattern 418 thereon.

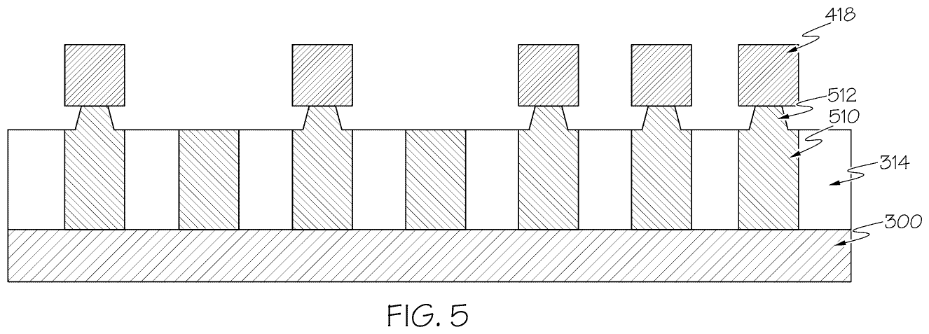

FIG. 5 is a cross-sectional view of an intermediate process, including recessing the preliminary conductive pattern 316 to form a second conductive pattern 510 and a second conductive via 512 (Block 206 in FIG. 2). The second conductive pattern 510 and the second conductive via 512 may correspond to the second conductive pattern 110 and the second conductive via 112 in FIG. 1, respectively. In some embodiments, one among the plurality of preliminary conductive patterns 316 having the mask pattern 418 thereon may become a second monolithic conductive structure comprising the second conductive pattern 510 and the second conductive via 512 thereon by the recessing. On the other hand, one among the plurality of preliminary conductive patterns 316 without the mask pattern 418 thereon may become the second conductive pattern 510 without the second conductive via 512 thereon by the recessing.

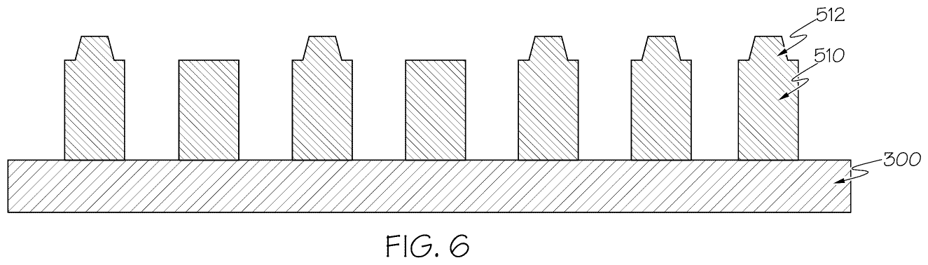

FIG. 6 is a cross-sectional view of an intermediate process, including removing the mask pattern 418 and the sacrificial layer 314 (Block 208 in FIG. 2). Herein, the process or series of processes forming the second conductive pattern 510 and the second conductive via 512 may be (referred to as) a top via scheme.

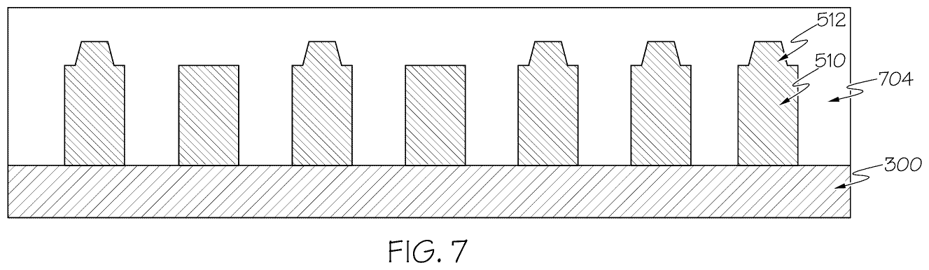

FIG. 7 is a cross-sectional view of an intermediate process, including forming a second insulating layer 704 (Block 210 in FIG. 2). The second insulating layer 704 may correspond to the second insulating layer 104 in FIG. 1. The second insulating layer 704 may extend around the second conductive pattern 510 and the second conductive via 512 on the substrate 300.

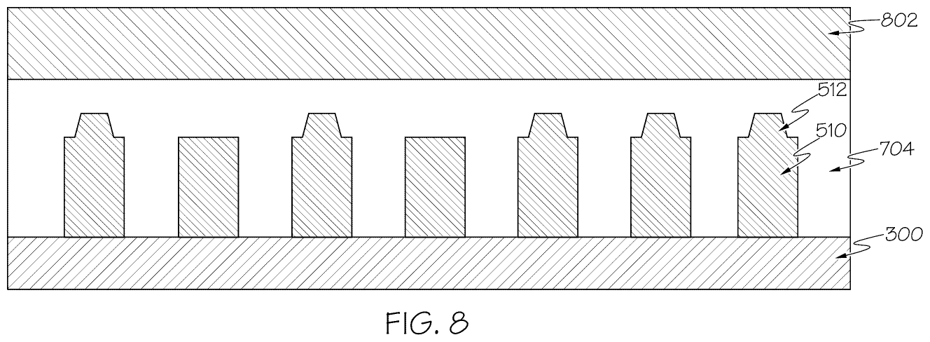

FIG. 8 is a cross-sectional view of an intermediate process, including forming a first insulating layer 802 on the second insulating layer 704 (Block 212 in FIG. 2). The first insulating layer 802 may correspond to the first insulating layer 102 in FIG. 1.

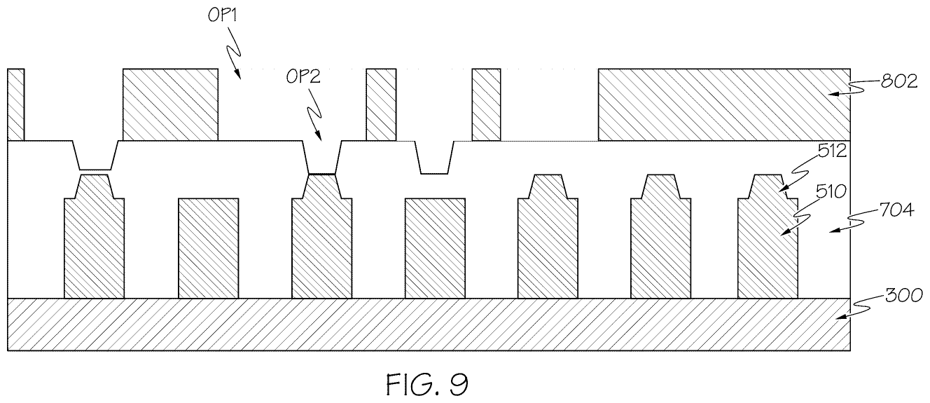

FIG. 9 is a cross-sectional view of an intermediate process, including forming a first opening OP1 in the first insulating layer 802 and a second opening OP2 in the second insulating layer 704 (Block 214 in FIG. 2). In some embodiments, the first opening OP1 may expose (an upper surface of) the second insulating layer 704. In some embodiments, the second opening OP2 may be recessed further from the first opening OP1 toward the second conductive pattern 510 and/or the second conductive via 512. In some embodiments, the first opening OP1 and the second opening OP2 may be connected to form a greater opening. In some embodiments, the second opening OP2 may expose (an upper surface of) the second conductive via 512.

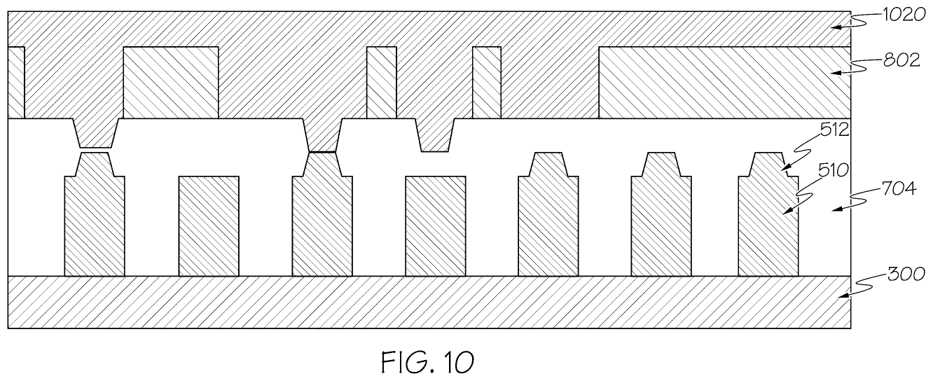

FIG. 10 is a cross-sectional view of an intermediate process, including forming a first conductive layer 1020 in the first opening OP1 and the second opening OP2 (Block 216 in FIG. 2). Referring to FIGS. 1 and 10, a portion of the first conductive layer 1020 may be removed to form the first conductive pattern 106 and the first conductive via 108 (Block 218 in FIG. 2). The portion of the first conductive layer 1020 may be removed by, for example, a CMP process, but the embodiments are not limited thereto. Herein, the process or series of processes forming the first conductive pattern 106 and the first conductive via 108 may be a damascene scheme.

Example embodiments described herein illustrate a dual conductive via scheme that utilizes both the top via scheme and the damascene scheme. The top via scheme may form a lower half conductive via, and the damascene scheme may form an upper half conductive via. The dual conductive via scheme can reduce process complexity and process difficulty while maintaining or increasing the total via height (the total aspect ratio) because the total via height can be achieved by forming the upper half conductive via and the lower half conductive via separately (e.g., embodiments illustrated in FIG. 1D).

Example embodiments described herein illustrate the upper half conductive via and/or the lower half conductive via protruding from one conductive pattern toward the other conductive pattern. As the distance between the conductive patterns opposite to each other in the first direction becomes closer to each other by the upper half conductive via and/or the lower half conductive via, the electrical breakdown for an e-fuse (e.g., an anti-fuse) can be triggered with a smaller voltage bias (e.g., embodiments illustrated in FIGS. 1A, 1B, and 1C). In some embodiments, the capacitance of a MOMCAP between the conductive patterns may increase by the upper half conductive vias and/or the lower half conductive vias because the conductive patterns and the half conductive vias thereon and may form monolithic conductive structures that have greater heights than those of the conductive patterns (e.g., embodiments illustrated in FIG. 1E). As described above, the dual conductive via scheme may improve design flexibility and device performance while reducing the process complexity.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete and will convey the scope of the disclosure to those skilled in the art. In the drawings, the sizes and relative sizes of layers and regions may be exaggerated for clarity. Like reference numbers refer to like elements throughout unless clearly stated otherwise.

Example embodiments of the present inventive concept are described herein with reference to cross-sectional views or plan views that are schematic illustrations of idealized embodiments and intermediate structures of example embodiments. As such, variations from the shapes of the illustrations as a result, for example, of manufacturing techniques and/or tolerances, are to be expected. Thus, example embodiments of the present inventive concept should not be construed as limited to the particular shapes illustrated herein but include deviations in shapes that result, for example, from manufacturing.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of the stated features, steps, operations, elements and/or components, but do not preclude the presence or addition of one or more other features, steps, operations, elements, components and/or groups thereof. As used herein the term “and/or” includes any and all combinations of one or more of the associated listed items.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination. For example, FIG. 1 includes embodiments of FIGS. 1A, 1B, 1C, 1D, and 1E. However, the combination of FIGS. 1A, 1B, 1C, 1D, and 1E illustrated in FIG. 1 is illustrative and not restrictive. The embodiments of FIGS. 1A, 1B, 1C, 1D, and 1E may be combined in different numbers and manners (e.g., may be omitted).

It should be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present inventive concept.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a substrate;
an insulating layer on the substrate;
a first conductive pattern on the insulating layer;
a second conductive pattern in the insulating layer, wherein the second conductive pattern is between the substrate and the first conductive pattern in a direction that is perpendicular to an upper surface of the substrate, and wherein the second conductive pattern is spaced apart from the first conductive pattern in the direction; and
a first via between the first conductive pattern and the second conductive pattern in the direction,
wherein the first via is in contact with one of the first conductive pattern and the second conductive pattern, and
wherein the first via is spaced apart from the other one of the first conductive pattern and the second conductive pattern in the direction.

2. The integrated circuit device of claim 1, wherein an upper surface or a lower surface of the first via is in contact with the insulating layer, and
wherein the first via, the other one of the first conductive pattern and the second conductive pattern, and the insulating layer are configured as an anti-fuse.

3. The integrated circuit device of claim 1, wherein the first via and the one of the first conductive pattern and the second conductive pattern include a first material.

4. The integrated circuit device of claim 3, wherein the first via and the one of the first conductive pattern and the second conductive pattern are integrated as a first monolithic conductive structure.

5. The integrated circuit device of claim 4, further comprising:
a second via between the first conductive pattern and the second conductive pattern in the direction,
wherein the second via is spaced apart from the one of the first conductive pattern and the second conductive pattern in the direction, and
wherein the second via is in contact with the other one of the first conductive pattern and the second conductive pattern.

6. The integrated circuit device of claim 5, wherein the second via and the other one of the first conductive pattern and the second conductive pattern include a second material.

7. The integrated circuit device of claim 6, wherein the second material is different from the first material.

8. The integrated circuit device of claim 7, wherein the second via and the other one of the first conductive pattern and the second conductive pattern are integrated as a second monolithic conductive structure.

9. The integrated circuit device of claim 8, wherein the first via overlaps the second via in the direction.

10. The integrated circuit device of claim 9, wherein the first via is spaced apart from the second via in the direction,
wherein an upper surface or a lower surface of the first via is in contact with the insulating layer, and
wherein an upper surface of a lower surface of the second via is in contact with the insulating layer.

11. The integrated circuit device of claim 10, wherein the first via, the second via, and the insulating layer are configured as an anti-fuse.

12. The integrated circuit device of claim 9, wherein the first via is in contact with the second via.

13. The integrated circuit device of claim 12, wherein the first via and the second via are configured as an interconnection structure between the first conductive pattern and the second conductive pattern.

14. An integrated circuit device comprising:
a substrate;
a first insulating layer on the substrate;
a set of first conductive patterns in the first insulating layer;
a second insulating layer between the first insulating layer and the substrate in a first direction that is perpendicular to an upper surface of the substrate;
a set of second conductive patterns in the second insulating layer, wherein the second conductive patterns are spaced apart from each other in a second direction that is parallel with the upper surface of the substrate; and
vias between the set of the first conductive patterns and the set of the second conductive patterns in the first direction,
wherein one of the vias protrudes from one among the set of the first conductive patterns and the set of the second conductive patterns in the first direction,
wherein the one of the vias is spaced apart from another one among the set of the first conductive patterns and the set of the second conductive patterns in the first direction, and
wherein the one among the set of the first conductive patterns and the set of the second conductive patterns is opposite to the another one among the set of the first conductive patterns and the set of the second conductive patterns in the first direction.

15. The integrated circuit device of claim 14, wherein adjacent ones among the vias are spaced apart from each other by the second insulating layer in the second direction.

16. The integrated circuit device of claim 15, wherein the adjacent ones of the vias and the second insulating layer therebetween are configured as a metal-oxide-metal capacitor.

17. The integrated circuit device of claim 14, wherein ones of the vias overlap in the first direction.

18. The integrated circuit device of claim 17, wherein the ones of the vias are in contact with each other.

19. A method of forming an integrated circuit device, the method comprising:
forming a set of first conductive patterns and a first via on a substrate by a first process; and
forming a set of second conductive patterns and a second via on the set of the first conductive patterns and the first via by a second process,
wherein the first via protrudes from one among the set of the first conductive patterns toward the set of the second conductive patterns and is spaced apart from the set of the second conductive patterns, and
wherein the second via protrudes from one among the set of the second conductive patterns toward the set of the first conductive patterns and is spaced apart from the set of the first conductive patterns.

20. The method of claim 19, wherein the first process is free of a damascene process, and
wherein the second process comprises a damascene process.
